(19) United States
(12) Patent Application Publication
(10) Pub. No.: US 2005/0072968 A1
(43) Pub. Date: Apr. 7, 2005

(54) LIGHT-EMITTING DEVICE

(76) Inventors: Tzong-Liang Tsai, Hsin-Chu City (TW); Chih-Sung Chang, Hsin-Chu City (TW); Wei-En Chien, Chia-I City (TW); Tzer-Perng Chen, Hsin-Chu City (TW)

Correspondence Address: NORTH AMERICA INTERNATIONAL PATENT OFFICE (NAIPC), P.O. BOX 506, MERRIFIELD, VA, 22116, US

(21) Appl. No.: 10/605,539

(22) Filed: Oct. 6, 2003

(51) Int. Cl. H01L 29/06

(52) U.S. Cl. 257/10

(57) ABSTRACT

The present invention discloses a light-emitting device that has a substrate, an n-type electrode, an active layer, a p-type semiconductor layer, a reflective layer, and a p-type electrode. The n-type electrode is located on the bottom surface of the substrate and the active layer is located on a top surface of the substrate. The p-type semiconductor layer covers the active layer. The reflective layer is located on the p-type semiconductor layer, and the p-type electrode covers the reflective layer. The reflective layer is a conductive layer with high reflectivity, and is formed under the p-type electrode to avoid light of the light-emitting device being absorbed by the metal electrode.

### BACKGROUND OF INVENTION

1. Field of the Invention

The invention relates to a semiconductor light-emitting device, and more particularly, to a light-emitting diode with high illumination efficiency.

2. Description of the Prior Art

FIG. 1 is a structural diagram of a light-emitting diode according to the prior art. As FIG. 1 shows, the light-emitting diode 10 comprises a substrate 11, a distributed Bragg reflector (DBR) 12, an active layer 13, a p-type semiconductor layer 14, a p-type electrode 15, and an n-type electrode 16 located under the substrate 11. The substrate 11 is an n-type GaAs substrate, and the DBR 12 is composed of multi-layered reflective structures for reflecting light. The active layer 13 is composed of an n-type AlGaInP lower cladding layer, an AlGaInP active layer, and a p-type AlGaInP upper cladding layer. The p-type semiconductor layer 14 is an ohmic contact layer, whose material can be AlGaAs, AlGaInP, or GaAsP. The p-type electrode 15 and the n-type electrode 16 are metal electrodes for wire bonding.

FIG. 2 is a structural diagram of another light-emitting diode according to the prior art. As FIG. 2 shows, the light-emitting diode 20 comprises a substrate 21, a distributed Bragg reflector (DBR) 22, an n-type semiconductor layer 27, an active layer 23, a p-type semiconductor layer 24, a p-type electrode 25, and an n-type electrode 26. The fabrication process of the light-emitting diode 20 is firstly forming the DBR 22, the n-type semiconductor layer 27, the active layer 23, and the p-type semiconductor layer 24 on the substrate 21. Then an etching process is performed to exposed portion of the n-type semiconductor layer 27, and the p-type electrode 25 is formed on the p-type semiconductor layer 24. Finally, the n-type electrode 26 is formed on the exposed n-type semiconductor layer 27. Similarly, the substrate 21 is a GaAs substrate, and the DBR 22 is composed of multi-layered reflective structures for reflecting light. The active layer 23 is composed of an n-type AlGaInP lower cladding layer, an AlGaInP active layer, and a p-type AlGaInP upper cladding layer. The p-type semiconductor layer 24 and the n-type semiconductor layer 27 are ohmic contact layers, whose material can be AlGaAs, AlGaInP, or GaAsP. The p-type electrode 25 and the n-type electrode 26 are metal electrodes for wire bonding.

However, when operating the above-mentioned light-emitting diodes, the p-type and n-type electrodes will absorb light from the active layer and lower the illumination efficiency.

### SUMMARY OF INVENTION

It is therefore a primary objective of the claimed invention to provide a light-emitting diode with high illumination efficiency to solve the above-mentioned problem. The light-emitting diode has a reflective layer located under the metal electrodes to avoid light being absorbed.

According to the claimed invention, a semiconductor light-emitting device comprises a substrate, an n-type electrode, an active layer, a p-type semiconductor layer, a reflective layer, and a p-type electrode. The n-type electrode is located on the bottom surface of the substrate, and the active layer is located on a top surface of the substrate. The p-type semiconductor layer covers the active layer. The reflective layer is located on the p-type semiconductor layer, and the p-type electrode covers the reflective layer. The reflective layer is a conductive layer with high reflectivity.

The claimed invention further discloses a semiconductor light-emitting device comprising a substrate, an n-type semiconductor layer, an active layer, an n-type electrode, a p-type semiconductor layer, a first reflective layer, and a p-type electrode. The n-type semiconductor layer covers the substrate, and the active layer and the n-type electrode separately cover portions of the n-type semiconductor layer. The p-type semiconductor layer covers the active layer. The first reflective layer is located on the p-type semiconductor layer, and the p-type electrode covers the first reflective layer. The semiconductor light-emitting device further comprises a second reflective layer located between the n-type semiconductor layer and the n-type electrode. The first reflective layer and the second reflective layer are both a conductive layer with high reflectivity.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a structural diagram of a light-emitting diode according to prior art.

FIG. 2 is a structural diagram of another light-emitting diode according to prior art.

FIG. 3 is a structural diagram of a light-emitting diode according to the present invention.

FIG. 4 is a structural diagram of another light-emitting diode according to the present invention.

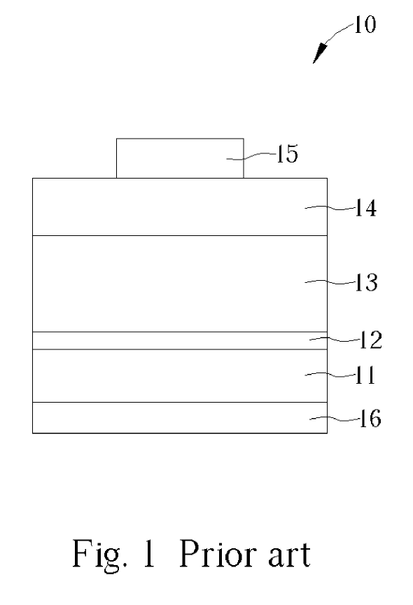

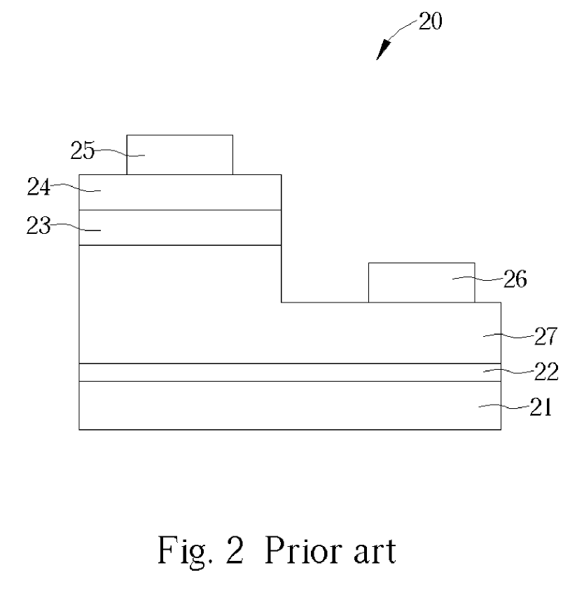

### DETAILED DESCRIPTION

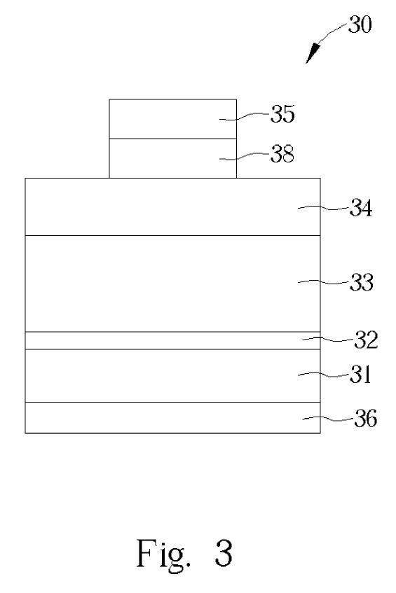

Please refer to FIG. 3, which is a structural diagram of a first embodiment of the present invention. A light-emitting diode 30 comprises a substrate 31, a distributed Bragg reflector (DBR) 32, an active layer 33, a p-type semiconductor layer 34, a p-type electrode 35, an n-type electrode 36, and a reflective layer 38. The fabrication process of the light-emitting diode 30 is firstly forming the DBR 32, the active layer 33, and the p-type semiconductor layer 34 on the substrate 31. Then the reflective layer 38 is formed on portion of the p-type semiconductor layer 34. Finally, the p-type electrode 35 is formed on the reflective layer 38, and the n-type electrode 36 is formed on the other surface of the substrate 31.

The substrate 31 is a conductive material, such as n-type GaAs or GaN, and the DBR 32 is composed of multi-layered reflective structures, such as AlAs and GaAs, for reflecting light. The structure of the active layer 33 is homostructure, single heterostructure, double heterostructure (DH), or multiple quantum well (MQW). If the structure of the active layer 33 is double heterostructure, it can be composed of an n-type AlGaInP lower cladding layer, an AlGaInP active layer, and a p-type AlGaInP upper cladding layer. Since the various structures of the active layer are known in the prior art, no more will be described in this paper. The p-type semiconductor layer 34 is an ohmic contact layer composed of a plurality of p-type III-V compound layers, such as Mg or Zn doped GaN, AlGaAs, AlGaInP, or GaAsP. The p-type electrode 35 and the n-type electrode 36 are metal electrodes for wire bonding.

The reflective layer 38 is a conductive layer with high reflectivity, such as silver (Ag), aluminum (Al), gold (Au), chromium (Cr), platinum (Pt), or rhodium (Rh), and the reflective layer 38 can be a single-layer or multi-layer structure. The reflective layer 38 is used for reflecting light from the active layer 33 to surroundings without being absorbed by the p-type electrode 35. In addition, the reflective layer 38 and the p-type semiconductor layer 34 can contact at a rough surface, the rough surface having an incline or a curved structure with a specific reflective angle to enhance the reflective layer 38. The reflective layer 38 can also be a scattering layer, such as a transparent conductive material comprising a plurality of diffusers, for partially reflecting light from the active layer 33 to reduce light being absorbed by the p-type electrode 35. The scattering layer has a more than 50% scattering rate.

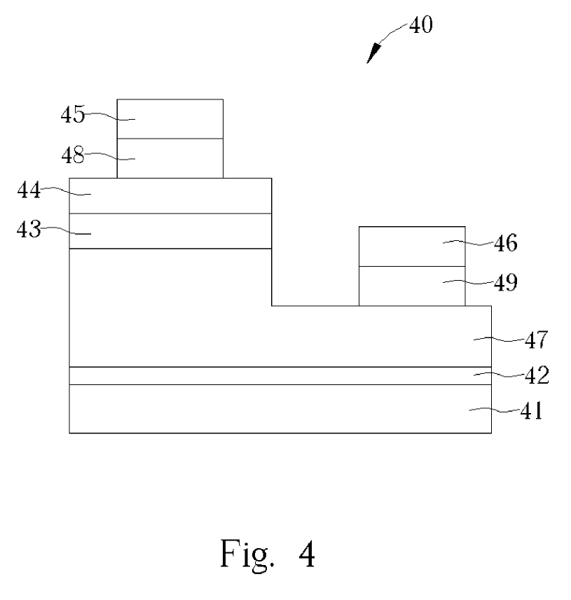

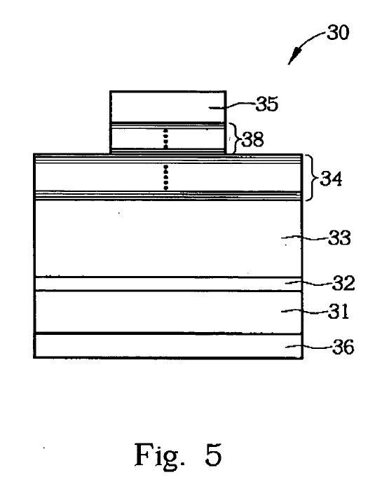

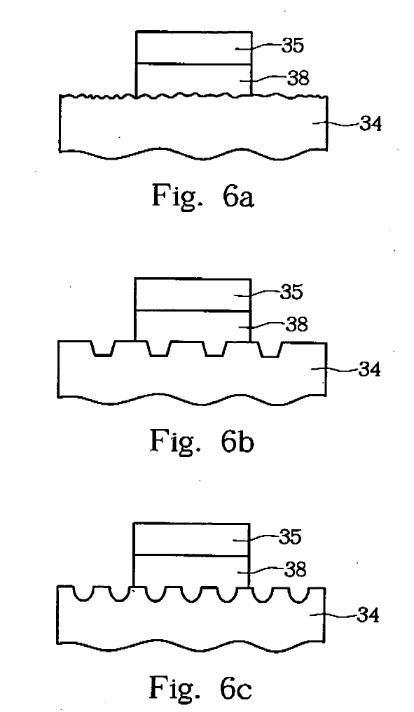

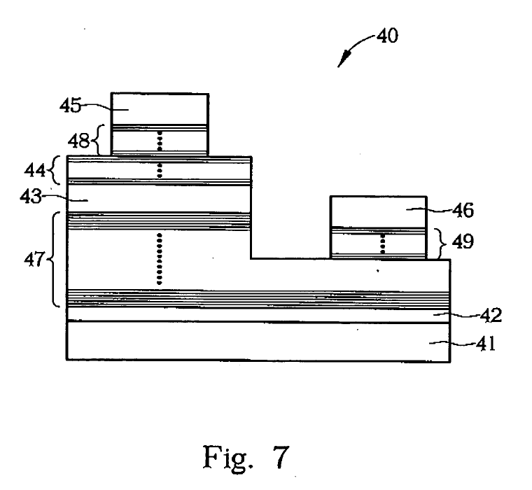

Please refer to FIG. 4, which is a structural diagram of the second embodiment of the present invention. As FIG. 4 shows, a light-emitting diode 40 comprises a substrate 41, a distributed Bragg reflector (DBR) 42, an active layer 43, a p-type semiconductor layer 44, a p-type electrode 45, an n-type electrode 46, an n-type semiconductor layer 47, a first reflective layer 48, and a second reflective layer 49. The fabrication process of the light-emitting diode 40 is firstly forming the DBR 42, the n-type semiconductor layer 47, the active layer 43, and the p-type semiconductor layer 44 on the substrate 41. Then an etching process is performed on portion of the p-type semiconductor layer 44 and the active layer 43 to expose portion of the n-type semiconductor layer 47. After that, the first reflective layer 48 and the p-type electrode 45 are formed on the un-etched p-type semiconductor layer 44, and the second reflective layer 49 and the n-type electrode 46 are formed on the exposed n-type semiconductor layer 47. The etching process can be wet etching process, dry etching process, or alternating both processes. Furthermore, the first reflective layer 48 and the second reflective layer 49 can be alternatively or simultaneously designed in the light-emitting diode 40 according to requirements.

In the second embodiment, the substrate 41 is a non-conductive material, such as sapphire, and the DBR 42, the active layer 43, and the p-type semiconductor layer 44 are similar to those in the first embodiment. The n-type semiconductor layer 47 is an ohmic contact layer composed of a plurality of n-type III-V compound layers, such as undoped GaN, Si doped GaN, AlGaAs, AlGaInP, or GaAsP. The p-type electrode 45 and the n-type electrode 46 are metal electrodes for wire bonding.

The first reflective layer 48 and the second reflective layer 49 are also conductive layers with high reflectivity, such as silver (Ag), aluminum (Al), gold (Au), chromium (Cr), platinum (Pt), or rhodium (Rh), and the first reflective layer 48 and the second reflective layer 49 can be single-layer or multi-layer structures. The first reflective layer 48 and the second reflective layer 49 are used for reflecting light from the active layer 43 to surroundings without being absorbed by the p-type electrode 45 and the n-type electrode 46. In addition, the reflective layers 48, 49 and the p-type and n-type semiconductor layers 44, 47 can contact at a rough surface, the rough surface having an incline or a curved structure with a specific reflective angle to enhance the reflective layers 48, 49. The reflective layers 48, 49 can also be a scattering layer, such as a transparent conductive material comprising a plurality of diffusers, for partially reflecting light from the active layer 43 to reduce light being absorbed by the p-type electrode 45 and the n-type electrode 46. The scattering layer has a more than 50% scattering rate.

In contrast to the prior art, the present invention having a reflective layer with high reflectivity can avoid light from the active layer being absorbed by the metal electrodes, and fully utilize light from the active layer.

Those skilled in the art will readily observe that numerous modifications and alterations of the device may be made while retaining the teachings of the invention. Accordingly, the above disclosure should be construed as limited only by the metes and bounds of the appended claims.

1. A semiconductor light-emitting device comprising:
a substrate;
an n-type electrode located on a bottom surface of the substrate;
an active layer located on a top surface of the substrate;
a p-type semiconductor layer covering the active layer;
a reflective layer located on the p-type semiconductor layer; and
a p-type electrode covering the reflective layer.

2. The semiconductor light-emitting device of claim 1 wherein the substrate is a conductive material.

3. The semiconductor light-emitting device of claim 1 wherein the p-type semiconductor layer comprises a plurality of p-type III-V compound layers.

4. The semiconductor light-emitting device of claim 1 wherein the reflective layer is a conductive layer with predetermined reflectivity, the reflective layer reflects light from the active layer to avoid light being absorbed by the p-type electrode.

5. The semiconductor light-emitting device of claim 4 wherein the reflective layer is a single-layer structure.

6. The semiconductor light-emitting device of claim 4 wherein the reflective layer is a multi-layer structure.

7. The semiconductor light-emitting device of claim 4 wherein the reflective layer comprises silver (Ag), aluminum (Al), gold (Au), chromium (Cr), platinum (Pt), or rhodium (Rh).

8. The semiconductor light-emitting device of claim 1 wherein the reflective layer is a conductive layer with predetermined scattering rate, the reflective layer partially reflects light from the active layer to reduce light being absorbed by the p-type electrode.

9. The semiconductor light-emitting device of claim 1 wherein the reflective layer and the p-type semiconductor layer contact at a rough surface, the rough surface having an incline or a curved structure with a specific reflective angle to enhance the reflective layer.

10. The semiconductor light-emitting device of claim 1 further comprising a distributed Bragg reflector (DBR) located between the substrate and the active layer.

11. A semiconductor light-emitting device comprising:
a substrate;
an n-type semiconductor layer covering the substrate;
an active layer and an n-type electrode separately covering portions of the n-type semiconductor layer;
a p-type semiconductor layer covering the active layer;
a first reflective layer located on the p-type semiconductor layer; and
a p-type electrode covering the first reflective layer.

12. The semiconductor light-emitting device of claim 11 wherein the substrate is a nonconductive material.

13. The semiconductor light-emitting device of claim 11 wherein the n-type semiconductor layer comprises a plurality of n-type III-V compound layers and the p-type semiconductor layer comprises a plurality of p-type III-V compound layers.

14. The semiconductor light-emitting device of claim 11 further comprising a second reflective layer located between the n-type semiconductor layer and the n-type electrode.

15. The semiconductor light-emitting device of claim 14 wherein the first reflective layer and the second reflective layer are both a conductive layer with predetermined reflectivity, the first reflective layer and the second reflective layer reflect light from the active layer to avoid light being absorbed by the p-type electrode and the n-type electrode.

16. The semiconductor light-emitting device of claim 15 wherein the second reflective layer and the n-type semiconductor layer contact at a rough surface, the rough surface having an incline or a curved structure with a specific reflective angle to enhance the second reflective layer.

17. The semiconductor light-emitting device of claim 15 wherein the first reflective layer and the second reflective layer are both a single-layer structure.

18. The semiconductor light-emitting device of claim 15 wherein the first reflective layer and the second reflective layer are both a multi-layer structure.

19. The semiconductor light-emitting device of claim 15 wherein the first reflective layer and the second reflective layer comprise silver (Ag), aluminum (Al), gold (Au), chromium (Cr), platinum (Pt), or rhodium (Rh).

20. The semiconductor light-emitting device of claim 14 wherein the first reflective layer and the second reflective layer are both a conductive layer with predetermined scattering rate, the first reflective layer and the second reflective layer partially reflect light from the active layer to reduce light being absorbed by the p-type electrode and the n-type electrode.

21. The semiconductor light-emitting device of claim 11 wherein the first reflective layer and the p-type semiconductor layer contact at a rough surface, the rough surface having an incline or a curved structure with a specific reflective angle to enhance the first reflective layer.

22. The semiconductor light-emitting device of claim 11 further comprising a distributed Bragg reflector (DBR) located between the substrate and the n-type semiconductor layer.
